(19) United States
(12) Patent Application Publication
(10) Pub. No.: US 2014/0362628 A1
(43) Pub. Date: Dec. 11, 2014

(54) MODULAR MULTIPLE CONVERTER COMPRISING REVERSE CONDUCTIVE POWER SEMICONDUCTOR SWITCHES

(71) Applicant: SIEMENS AKTIENGESELLSCHAFT, MUENCHEN (DE)

(72) Inventor: Hans-Guenter Eckel, Rostock (DE)

(21) Appl. No.: 14/008,068

(22) PCT Filed: Mar. 14, 2012
(86) PCT No.: PCT/EP12/54462

§ 371 Date: Sep. 27, 2013

(30) Foreign Application Priority Data
Mar. 29, 2011 (DE) 10 2011 006 345.5

(51) Int. Cl. H02M 1/00; H02M 7/483; H01L 25/00

(52) U.S. Cl. CPC H02M 1/00; H01L 25/00; H02M 7/483; H02M 2007/4835
USPC 363/132; 361/729

(57) ABSTRACT

A submodule for a modular multilevel converter has at least one unipolar energy storage device, first and second connection terminals and a power semiconductor circuit with power semiconductor switches that are driven with a control signal and freewheeling diodes connected in parallel with an assigned power semiconductor switch in the opposite sense. Depending on the driving of the power semiconductor switches, the voltage across the energy storage device(s) or else a zero voltage can be generated between the first and second connection terminals. The power semiconductor circuit forms a bridging branch between the potential points of the first and second connection terminals. Only the power semiconductor switches in the bridging branch are reverse conductive power semiconductor switches. The submodule has low on-state losses during normal operation and is also cost-effective.

The invention relates to a submodule for a modular multilevel converter comprising at least one unipolar energy storage device, a first and a second connection terminal and a power semiconductor circuit comprising power semiconductor switches that can be turned on and off by means of a control signal and free-wheeling diodes connected in parallel with an assigned power semiconductor switch in the opposite direction, wherein, depending on the control of the power semiconductor switches, the voltage dropping across one or all of the energy storage devices or else a zero voltage can be generated between the first and the second connection terminals, and wherein the power semiconductor circuit forms a bridging branch situated between the potential points of the first and second connection terminals.

A submodule of this kind is already known by way of example from DE 101 03 031. A multilevel converter is disclosed therein which has phase modules which each have an alternating voltage connection for a phase of an alternating voltage network to be connected and two direct voltage connections which are provided for connection of a direct voltage intermediate circuit. A phase module branch extends between the alternating voltage connection and each direct voltage connection. The two phase module branches of a phase module are connected to the remaining phase module branches like what is known as a “graetz bridge”. Each phase module branch has a series circuit comprising submodules which are each equipped with a unipolar storage capacitor. Connected in parallel with the storage capacitor is a series circuit comprising two power semiconductor switches that can be turned on and off and with which one free-wheeling diode respectively is connected in parallel in the opposite direction. Said controllable power semiconductor switches are arranged in the series circuit with the same forward direction. The known submodule also has two connection terminals, wherein one connection terminal is directly connected to a pole of the storage capacitor and the other connection terminal is connected to the potential point which is situated between the two controllable power semiconductor switches. Depending on the control of the power semiconductor switches, either the capacitor voltage dropping across the storage capacitor or else a zero voltage can therefore be applied at the two connection terminals of each submodule. As a result of the series connection the total voltage of each phase module branch can be adjusted in stages, wherein the level of the stages is fixed by the voltage dropping across the storage capacitor.

Controllable power semiconductor switches that can be turned on and off are also known from practical experience which are reverse conductive. These power semiconductor switches no longer require free-wheeling diodes connected in parallel in the opposite direction therefore. Compared to non-reverse conductive power semiconductor switches, reverse conductive power semiconductor switches have the advantage that a lower forward voltage drops across them during normal operation, so losses are reduced compared with non-reverse conductive power semiconductor switches. The reverse conductive power semiconductor switches have the inherent disadvantage, however, that they are expensive compared to the power semiconductor switches without reverse conductivity which are already commercially available.

The object of the invention is therefore to provide a submodule of the type mentioned in the introduction which has lower losses during normal operation and is also inexpensive.

The invention achieves this object in that only the power semiconductor switches arranged in the bridging branch are reverse conductive power semiconductor switches.

Within the scope of the invention a submodule for a modular multilevel converter is provided which has reverse conductive power semiconductor switches. Since submodules of the type mentioned in the introduction and reverse conductive power semiconductor switches are both known, complete replacement of the previously used non-reverse conductive power semiconductor switches with reverse conductive power semiconductor switches would be obvious. A submodule of this kind would then be identified in each case by lower forward voltages and therefore lower operating losses than a known submodule. According to the invention it has, however, been recognized that power semiconductor switches, which are arranged between the connection terminals, are stressed to a greater level than power semiconductor switches which are not arranged between the connection terminals. This recognition is the result of complex calculations and simulations which are not intended to be a subject matter of the present invention. As a result of this recognition, within the scope of the invention the reverse conductive controllable power semiconductor switches that can be turned on and off are arranged solely in the bridging branch of the submodule which is situated between the potential points of the connection terminals. These are therefore the power semiconductor switches which during normal operation of the submodule are heavily stressed, in particular in the case of applications in the field of energy transfer and distribution. The use of reverse conductive power semiconductor switches that can be turned on and off means the forward voltage can be reduced. Within the scope of the invention the less heavily stressed power semiconductor switches are power semiconductor switches which do not have reverse conductivity and with which therefore, as is known from the prior art, free-wheeling diodes are connected in parallel in the opposite direction. These power semiconductor switches are significantly less expensive to obtain. Since the less expensive power semiconductor switches are used only at less heavily stressed parts of the submodule, the losses, which result owing to an increased forward voltage, are acceptable.

According to a preferred embodiment of the invention a unipolar energy storage device is provided with which a series circuit comprising power semiconductor switches that can be turned on and off and with an identical forward direction is connected in parallel, wherein the first connection terminal is connected to a first pole of the energy storage device and the second connection terminal is connected to a potential point situated between the controllable power semiconductor switches. The circuit of a submodule of this kind is basically known, wherein, however, according to the invention the heavily stressed power semiconductor switch is a reverse conductive power semiconductor switch. During operation this power semiconductor switch is heavily stressed so the use of just one reverse conductive power semiconductor switch in the bridging branch between the connection terminals is already enough to reduce operating losses. The power semiconductor switch not situated between the connection terminals is, as in the prior art, a non-reverse conductive power semiconductor switch with which a free-wheeling diode is connected in parallel in the opposite direction.

In a departure from this, according to a further variant of the invention a first energy storage device and a second energy storage device, connected in series with respect to the first energy storage device, are provided and two reverse conductive power semiconductor switches with identical forward direction are arranged in the bridging branch, wherein the potential point between the reverse conductive power semiconductor switches is connected to the potential point between the first and the second energy storage devices, and wherein the bridging branch is connected by a first power semiconductor switch with a first free-wheeling diode in the opposite direction to a pole of the second energy storage device and by a second power semiconductor switch with a free-wheeling diode in the opposite direction to a pole of the first energy storage device, so the bridging branch is switched between the non-reverse conductive power semiconductor switches, and wherein all power semiconductor switches are arranged in series and with the same forward direction. According to this advantageous development a double module is provided which is likewise known as such. Within the scope of the invention only the power semiconductor switches situated between connection terminals are chosen as reverse conductive power semiconductor switches in the case of said double module since these power semiconductor switches are more heavily stressed during operation of a multilevel converter than the power semiconductor switches which are not situated between the connection terminals.

According to a preferred embodiment of the invention each reverse conductive power semiconductor switch is of such a kind that an optimally low forward voltage drops across it. Reverse conductive power semiconductor switches, by way of example reverse conductive Insulated Gate Bipolar Transistors (IGBT) may be optimized in different ways. An interaction between what is known as the “reverse recovery charge” in diode mode on one hand and the forward voltage in the diode mode and power semiconductor switching mode on the other hand exist in this connection. A low reverse recovery charge therefore leads to higher forward voltages in the IGBT and in the diode mode. Optimization of the reverse conductive IGBT can therefore lead either to lower forward losses or else to low switching losses. According to this advantageous development the reverse conductive power semiconductor switches are optimized for low forward voltages.

A control unit for controlling the controllable power semiconductor switches is expediently provided, wherein the control unit is set up such that the non-reverse conductive power semiconductor switches can be turned on more slowly compared with all the reverse conductive controllable power semiconductor switches. If the power semiconductor switch(es) arranged between the connection terminals is/are optimized for low forward voltages, high storage charges result if the reverse conductive power semiconductor switch acts as a diode, i.e. conducts a current counter to its switchable forward direction. The high storage charges of the reverse conductive power semiconductor switches lead in the case of the non-reverse conductive power semiconductor switch(es) connected in series to high turn-on losses but the high turn-on losses are less disruptive in the case of the less heavily stressed power semiconductor switches which are not arranged in the bridging branch since these power semiconductor switches, as has been recognized within the scope of the invention, are less heavily stressed. The high turn-on currents are limited by slower turning on, so the risk of these power semiconductor switches being destroyed is reduced.

According to a further expedient development the power semiconductor switches not arranged in the bridging branch are optimized such that they have an optimally low storage charge. The low storage charge in turn minimizes the switch-on losses in the power semiconductor switches, connected in series, of the bridging branch which are reverse conductive and particularly heavily stressed. The switch-on losses of the heavily stressed reverse conductive power semiconductor switches are minimized in this way. The higher forward losses of the less heavily stressed power semiconductor switches are less disruptive.

A control unit for controlling the controllable power semiconductor switches is expediently provided, wherein the control unit is set up such that the non-reverse conductive power semiconductor switches can be turned on more slowly compared with the reverse conductive controllable power semiconductor switches. This reduces the losses which occur in the case of the reverse conductive power semiconductor switches in diode mode owing to the high storage charges, at the expense of the turn-on losses of the non-reverse conductive power semiconductor switches. This is advantageous since the latter are less heavily stressed.

The invention also relates to a multilevel converter with a submodule as claimed in any one of the preceding claims.

Further expedient developments and advantages of the invention are the subject matter of the following description of exemplary embodiments of the invention with reference to the figures in the drawings, wherein identical reference characters denote components with the same effect and wherein

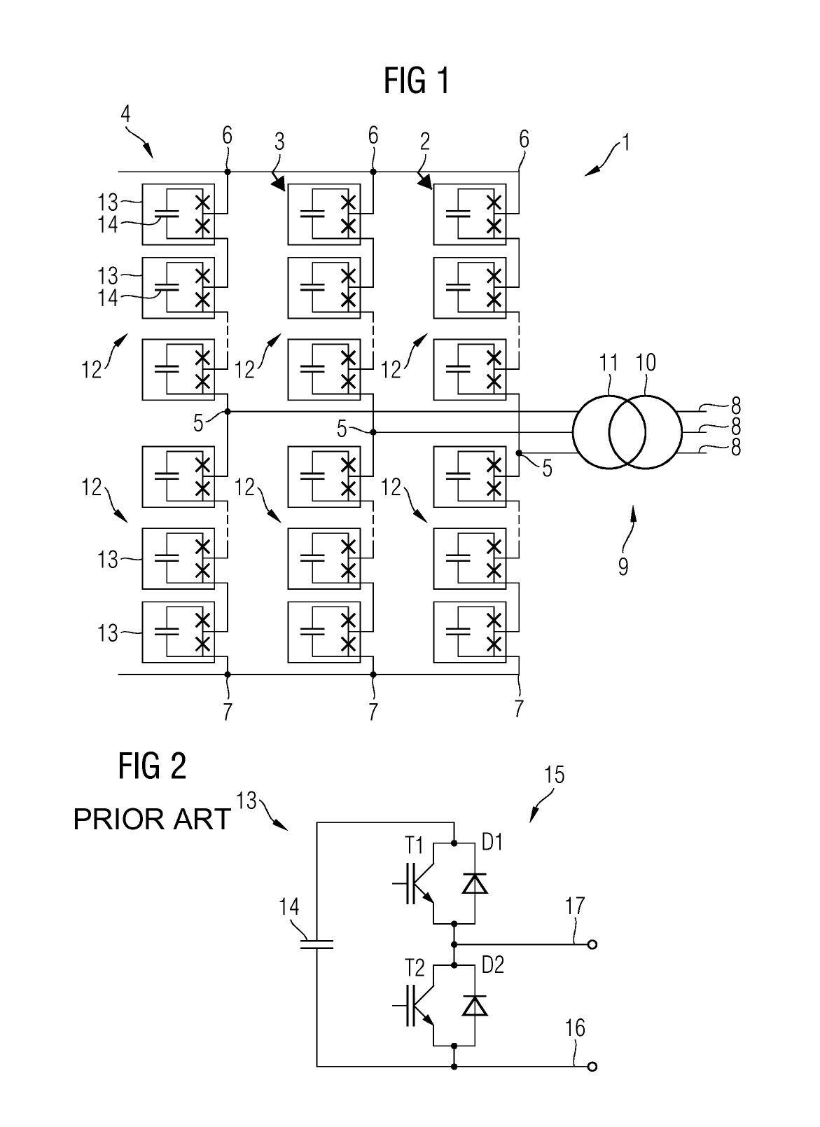

FIG. 1 shows an exemplary embodiment of the inventive multilevel converter,

FIG. 2 shows a submodule according to the prior art,

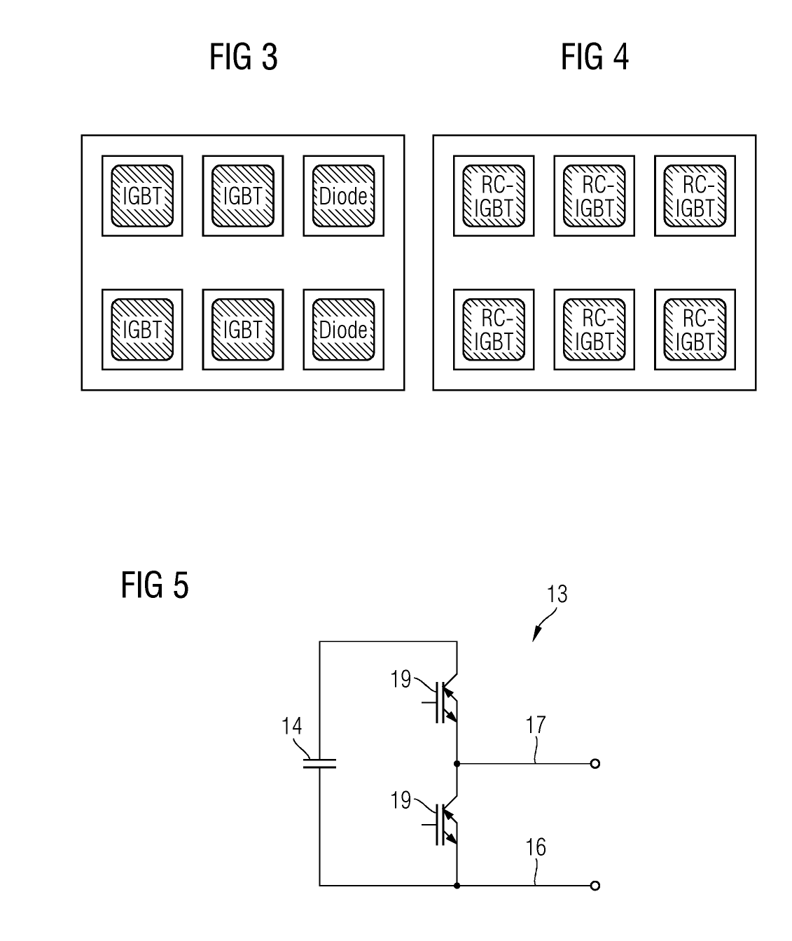

FIG. 3 shows a substrate of an IGBT as a power semiconductor switch with free-wheeling diode connected in parallel in the opposite direction,

FIG. 4 shows a substrate of a reverse conductive power semiconductor switch,

FIG. 5 shows a submodule according to FIG. 2 which has only verse conductive power semiconductor switches,

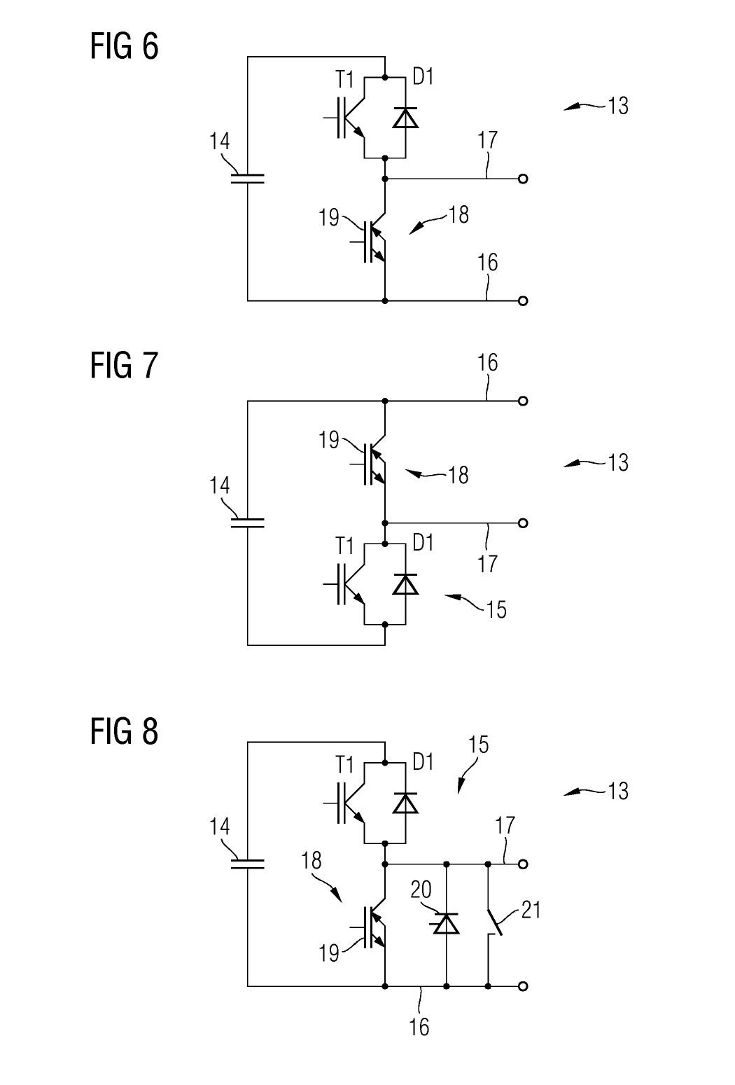

FIG. 6 shows an exemplary embodiment of the inventive submodule,

FIG. 7 shows a further exemplary embodiment of the inventive submodule,

FIG. 8 shows the submodule according to FIG. 7 with bridging switches and

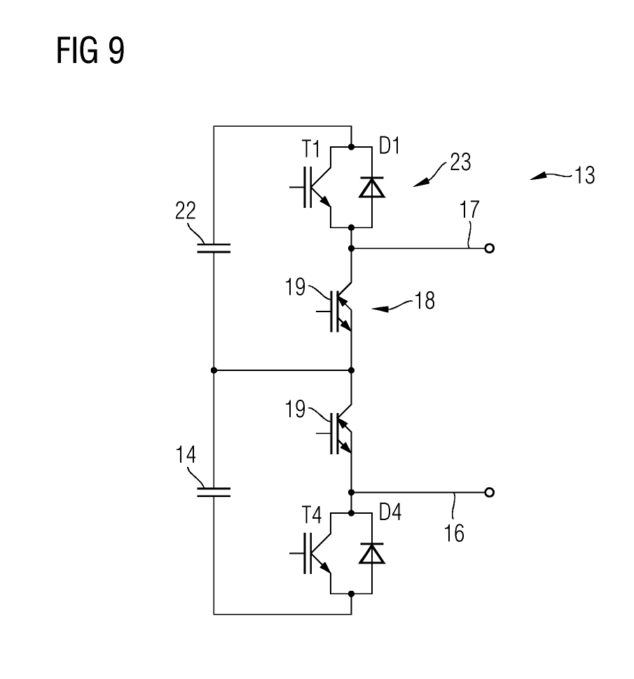

FIG. 9 shows a further exemplary embodiment of the inventive submodule.

FIG. 1 shows an exemplary embodiment of the inventive multilevel converter in a schematic diagram. It can be seen that the multilevel converter has three phase modules 2, 3 and 4, wherein each of the phase modules 2, 3, 4 has an alternating voltage connection 5 and two direct voltage connections 6 and 7. Each alternating voltage connection 5 is connected to a phase 8 of an alternating voltage network (not shown in the figures). A transformer 9 with a primary winding 10 and a secondary winding 11 is used for galvanic isolation between the converter 1 and the alternating voltage network. Each of the phase modules 2, 3 and 4 forms two phase module branches 12 between the alternating voltage connection 5 and each of the direct voltage connections 6 and 7. The phase module branches of all phase modules 2, 3, 4 are connected to each other to form a bridge circuit. Each phase module branch has a series circuit comprising submodules T3 which are each equipped with one or more unipolar capacitor(s) 14 as the energy storage device.

FIG. 2 shows the embodiment of a submodule according to the prior art. It can be seen that the submodule has a unipolar capacitor 14 with which a series circuit 15 is connected in parallel and in which two power semiconductor switches T1 and T2 that can be turned on and off by means of a control signal are connected in series. Said power semiconductor switches T1 and T2 are non-reverse conductive, so one free-wheeling diode D1 or D2 respectively is connected with them in parallel in the opposite direction. The potential point between the controllable power semiconductor switches T1 and T2 or between the free-wheeling diodes D1 and D2 is connected to a second connection terminal 17, wherein one pole of the storage capacitor 14 is connected to a first connection terminal 16. In the illustrated example the power semiconductor switches T1 a T2 are what are known as an IGBT, it being possible, however, to also use other power semiconductor switches that can be turned on and off such as GTO, IGCTs or the like.

If the power semiconductor switch T1 is transferred into its forward position, in which a current flow across T1 in the illustrated passage direction is enabled, the power semiconductor switch T2 has to be transferred into its blocking position to avoid a short circuit of the storage capacitor 14. The same applies in the reverse case. If the power semiconductor switch T1 is switched into its passage position therefore, the power semiconductor switch T2 is transferred into a locking position, so the capacitor voltage of the U_{c} storage capacitor 14 drops across the connection terminals 16 and 17. In the reverse case the first connection terminal 16 is connected by the power semiconductor switch T2 that can be turned off to the first connection terminal, so a zero voltage drops across the connection terminals 16, 17. In a phase module branch 12 shown in FIG. 1 which has by way of example submodules 13 according to FIG. 2 in a series connection, the voltage, which drops across the entire phase module branch 12, can therefore be increased and reduced in stages, wherein the level of the stages is determined by the level of the capacitor voltage U_{c}. This is of course guided by the blocking capacity of the power semiconductor switches T1 or T2. According to the current prior art this is between 1 kV and 10 kV. In high-voltage applications several hundred submodules 12 are therefore connected in series. Alternatively, the power semiconductor switches T1 and T2 can also stand for a series circuit of power semiconductor switches, so the blocking voltage of the switches, and therefore the level of the voltage stages, is increased.

Reverse conductive power semiconductor switches are also known from the prior art that can be turned on and off by means of a control signal in their passage direction and are also conductive counter to their switchable passage direction. In other words, a current flow in the passage direction can be interrupted if the reverse conductive power semiconductor switch is transferred into its blocking position. The current flow across the reverse conductive power semiconductor switches in the passage direction can then only be enabled if it is actively transferred from its blocking position into its passage position by means of a control signal. For a current which flows in a direction opposing that of the forward direction, the reverse conductive power semiconductor switch always remains conductive independent of the applied control signal. The power semiconductor switch therefore acts like a diode for this current direction. Parallel connection of a diode in the opposite direction has become unnecessary due to the return conductivity.

FIG. 3 shows a substrate of a non-reverse conductive IGBT with free-wheeling diode connected in the opposite direction. It can be seen that four semiconductor chips are arranged on a substrate for the IGBT that can be turned on and off, wherein two chips are provided for the diode.

FIG. 4 shows a substrate of a reverse conductive IGBT which is designated there by RC-IGBT. It can be seen that six RC-IGBT chips are arranged on a substrate. All chips are therefore used in the case of a reverse conductive IGBT in both the forward and the opposing “diode” directions. In the case of a non-reverse conductive IGBT, as is shown schematically in FIG. 3, by contrast only four chips are used in the passage direction and two chips are used in the diode mode. In the case of a reverse conductive IGBT the current flow is therefore distributed among more semiconductor chips in both directions. For this reason alone the reverse conductive IGBT has a lower passage voltage than a correspondingly designed power semiconductor switch without reverse conductivity. It is therefore obvious to equip a submodule according to FIG. 2 with only reverse conductive IGBTs 19, as is shown in FIG. 5.

FIG. 6 shows an exemplary embodiment according to the present invention. Compared with FIG. 2 it can be seen that a reverse conductive power semiconductor switch 19 is arranged in the bridging branch 18 extending between the connection terminals 16 and 17. Outside of the bridging branch 18 a non-reverse conductive IGBT T1 is provided, however, with which a diode D1 is in turn connected in parallel in the opposite direction. Compared to the submodule illustrated in FIG. 5, the submodule according to FIG. 6 is therefore significantly less expensive. By way of complex calculations it may be discovered that, in particular in applications in the field of energy transfer, the power semiconductor switch T2 arranged in the bridging branch 18 or 19 is more heavily stressed than the power semiconductor switch T1. According to the invention it is therefore quite sufficient to arrange the more expensive reverse conductive IGBT only in the bridging branch 18 but not outside of the bridging branch 18.

The reverse conductive IGBT 19 can accordingly be optimized in two directions. On the one hand it can be adjusted such that a lower forward voltage drops across it. The forward voltage is the voltage which drops across the power semiconductor switch 19 for both current directions. A low forward voltage has lower losses as a result. If, however, the reverse conductive IGBT is optimized such that it has low forward voltages in the IGBT and diode modes, then for physical reasons this is at the expense of high reverse recovery charges. A high reverse recovery charge results in high turn-on losses, however.

If in FIG. 6 a current accordingly flows from the first connection terminal 16 across the reverse conductive IGBT to connection terminal 17 in diode mode, then, owing to the high reverse recovery charges of the reverse conductive IGBT 19, it can happen that when T1 is turned on, i.e. when the non-reverse conductive power semiconductor switch T1 is transferred from its blocking position to its pass position, such an excessive current flows across T1 that it is destroyed. For this reason it is connected within the scope of one exemplary embodiment of the invention to a control unit which by way of the gate connection of T1 provides for slower turning-on of T1 compared with the switching off operation of the IGBT. Destruction of T1 is thus prevented. Since the non-reverse conductive power semiconductor switch T1 is stressed less heavily than the reverse conductive power semiconductor switch 19 it still has thermal reserves, so the high turn-on losses can be accepted in the wake of generation of heat. If with a current flow from connection terminal 17 across the reverse conductive power semiconductor switch 19 to the connection terminal 16 the power semiconductor switch 19 is transferred into its blocking position, high turn-off losses occur but these can be accepted in view of lower forward losses.

FIG. 7 shows a further exemplary embodiment of the invention. It can be seen that compared to FIG. 6 the first connection terminal 16 is connected to a different pole of the unipolar storage capacitor 14. A reverse conductive IGBT is again arranged in the bridging branch 18 while the power semiconductor switch, which is not situated between the connection terminals 16 and 17, again a non-reverse conductive IGBT is arranged with a parallel free-wheeling diode D1 in the opposite direction.

FIG. 8 shows the exemplary embodiment of the invention according to FIG. 6, wherein, however, the submodule 13 can be bridged with a thyristor 20 or a mechanical switch 21. This is necessary in the case of a fault to be able to bridge the faulty submodule in phase module branch 12, so operation of the converter can be continued.

FIG. 9 shows a further exemplary embodiment of the inventive submodule 13 which can also be called a double module. In contrast to previously presented submodules 13, the submodule 13 shown in FIG. 9 has a series connection comprising two storage capacitors 14 and 22. A series circuit comprising power semiconductor switches 23 is connected in parallel with the series circuit comprising storage capacitors 14 and 22. The bridging branch 18 is integrated in the series circuit 23. The bridging branch 18 is situated between the potential points of the first 16 and second connection terminals 17. Two reverse conductive power semiconductor switches 19 that can be turned on and off by means of a control signal are arranged in the bridging branch 18. The potential point between said power semiconductor switches 19 is connected to the potential point between the storage capacitors 14 and 22. The collector of the first power semiconductor switch T1 is connected to a free terminal or the free pole of the second storage capacitor 22. A free-wheeling diode D1 is again connected in parallel and in the opposite direction with this first non-reverse conductive power semiconductor switch T1. A fourth power semiconductor switch T4 is also provided which connects the bridging branch 18 to a free pole or a terminal of the first storage capacitor 14. For this purpose the emitter of the non-reverse conductive power semiconductor switch T4 is connected to said terminal of the storage capacitor 14. A free-wheeling diode is again connected in parallel in the opposite direction with the power semiconductor switch T4. According to this circuit either the voltage dropping across the storage capacitor 14 or storage capacitor 22 can accordingly be applied to the connection terminals 16, 17. The total voltage, i.e. the total of the voltage of the storage capacitor 14 and the voltage of the storage capacitor 22, can also be produced between the connection terminals 16 and 17.

The second and third power semiconductor switches 19 of the series circuit 23 are reverse conductive power semiconductor switches 19. Both are in turn designed for low forward losses and form a comparatively high reverse recovery charge. To avoid destruction of T1 and T4, compared with the switching times of the reverse conductive power semiconductor switch 19 in the bridging branch 18, these are turned on slowly by a control unit (not shown). The statements made with regard to the switch according to FIG. 6 apply accordingly here, moreover. In particular the switches 19 arranged in the bridging branch 18 are more heavily stressed than the switches T1 and T4 arranged in the bridging switch.

1-7. (canceled)

8. A submodule for a modular multilevel converter, the submodule comprising:
at least one unipolar energy storage device;
first and second connection terminals; and
a power semiconductor circuit containing power semiconductor switches configured to be turned on and off by way of a control signal and free-wheeling diodes connected in parallel with a respectively assigned power semiconductor switch in an oppositely conducting direction, wherein, depending on a control of said power semiconductor switches, a voltage dropping across said at least one energy storage device, or a zero voltage, is generated between said first and second connection terminals;
said power semiconductor circuit forming a bridging branch between potential points of said first and second connection terminals; and
wherein only said power semiconductor switches arranged in said bridging branch are reverse-conductive power semiconductor switches.

9. The submodule according to claim 8, wherein said at least one energy storage device is one unipolar energy storage device having a series circuit connected in parallel therewith, said series circuit containing controllable power semiconductor switches to be turned on and off and having a common forward direction, wherein said first connection terminal is connected to a pole of said energy storage device and said second connection terminal is connected to a potential point between said controllable power semiconductor switches of said series circuit.

10. The submodule according to claim 8, wherein:
said at least one energy storage device is one of a plurality of energy storage devices, including a first energy storage device and a second energy storage device connected in series with one another;
two reverse conductive power semiconductor switches with a common forward direction are connected in said bridging branch;
a potential point between said reverse conductive power semiconductor switches is connected to a potential point between said first and second energy storage devices;
said bridging branch is connected by way of a first power semiconductor switch with a first free-wheeling diode in an opposite direction to said second energy storage device and by way of a second power semiconductor switch with a free-wheeling diode in an opposite direction to said first energy storage device, so that said bridging branch is connected between said non-reverse conductive power semiconductor switches; and
all of said power semiconductor switches are connected in series and with a common forward direction.

11. The submodule according to claim 8, wherein each reverse conductive power semiconductor switch is optimized to have an optimally low forward voltage drop there-across.

12. The submodule according to claim 8, which comprises a control unit for controlling said controllable power semiconductor switches, wherein said control unit is configured to turn on said non-reverse conductive power semiconductor switches more slowly than said reverse conductive controllable power semiconductor switches.

13. The submodule according to claim 8, wherein said diodes that are not connected in said bridging branch are optimized to have an optimally low storage charge.

14. A multilevel converter, comprising a submodule according to claim 8.
